(19) United States
(12) Patent Application Publication
(10) Pub. No.: US 2026/0303038 A1
(43) Pub. Date: Oct. 1, 2026

(54) LOW-NOISE AMPLIFIER CIRCUIT

(71) Applicant: Murata Manufacturing Co., Ltd., Kyoto (JP)

(72) Inventors: Ryota OCHI, Nagaokakyo-shi (JP); Koudai SUGIYAMA, Nagaokakyo-shi (JP); Masamichi TOKUDA, Nagaokakyo-shi (JP); Kenji FURUSAWA, Nagaokakyo-shi (JP)

(73) Assignee: Murata Manufacturing Co., Ltd., Nagaokakyo-shi (JP)

(21) Appl. No.: 19/574,476

(22) Filed: Mar. 23, 2026

(30) Foreign Application Priority Data
Mar. 31, 2025 (JP) 2025-059139

(51) Int. Cl. H03F 1/56; H03F 1/26; H03F 3/24

(52) U.S. Cl. CPC H03F 1/565; H03F 1/26; H03F 3/245; H03F 2200/222; H03F 2200/294; H03F 2200/451

(57) ABSTRACT

A low-noise amplifier circuit includes an input terminal, an output terminal, an amplifier connected between the input terminal and the output terminal, a limiter circuit including a first diode and a second diode connected in parallel in opposite directions between a ground and a path connecting the input terminal to the input end of the amplifier, a matching circuit including an inductor connected between the ground and the path connecting the input terminal to the input end of the amplifier, and a capacitor connected between the limiter circuit and the ground and between the matching circuit and the ground.

### CROSS-REFERENCE TO RELATED APPLICATION

This application claims priority under 35 U.S.C. §119 to Japanese Patent Application No. 2025-059139, filed on Mar. 31, 2025, the entire contents of which are incorporated herein by reference.

### BACKGROUND

### 1. Field

The present disclosure relates to a low-noise amplifier circuit.

### 2. Description of the Related Art

Japanese Unexamined Patent Application Publication No. 2020-191551 discloses a low-noise amplifier circuit including an input matching circuit and a limiter circuit that are connected to the input side of an amplifier.

### SUMMARY

However, with the related-art technology described above, it is desired to improve the noise figure (NF) of the low-noise amplifier circuit.

For the above reason, the present disclosure is directed to providing a low-noise amplifier circuit with an improved NF.

A low-noise amplifier circuit according to an aspect of the present disclosure includes an input terminal; an output terminal; an amplifier that is connected between the input terminal and the output terminal; a limiter circuit including two diodes that are connected in parallel in opposite directions between a ground and a path connecting the input terminal to an input end of the amplifier; a matching circuit including a first inductor that is connected between the ground and the path connecting the input terminal to the input end of the amplifier; and a first capacitor that is connected between the limiter circuit and the ground and between the matching circuit and the ground.

An aspect of the present disclosure makes it possible to improve the NF of a low-noise amplifier circuit.

### BRIEF DESCRIPTION OF THE DRAWINGS

FIG. 1 is a circuit diagram of a low-noise amplifier circuit according to a first embodiment;

FIG. 2 is a layout diagram of the low-noise amplifier circuit according to the first embodiment;

FIG. 3 is a plan view of a first layer of a capacitor and a matching circuit according to the first embodiment;

FIG. 4 is a plan view of a second layer of the matching circuit according to the first embodiment;

FIG. 5 is a plan view of a third layer of the matching circuit according to the first embodiment;

FIG. 6 is a layout diagram of a low-noise amplifier circuit according to a second embodiment.

FIG. 7 is a plan view of a first layer of a capacitor and a matching circuit according to the second embodiment;

FIG. 8 is a plan view of a second layer of the matching circuit according to the second embodiment;

FIG. 9 is a plan view of a third layer of the matching circuit according to the second embodiment; and

FIG. 10 is a circuit diagram of a low-noise amplifier circuit according to another embodiment.

### DESCRIPTION OF THE EMBODIMENTS

Embodiments of the present disclosure are described in detail below with reference to the drawings. Each of the embodiments described below represents a general or specific example. Values, shapes, materials, components, and the layouts and connection configurations of the components described in the embodiments below are just examples and are not intended to limit the present disclosure.

Each of the drawings is a schematic diagram in which components are emphasized or omitted and the ratios between the components are adjusted to facilitate the understanding of the present disclosure. That is, components in each of the drawings are not necessarily illustrated accurately; and the shapes, positional relationships, and ratios of the components may differ from the actual shapes, positional relationships, and ratios. The same reference number is assigned to substantially the same components in the drawings, and repeated descriptions of those components may be omitted or simplified.

In the drawings described below, the x-axis and the y-axis are orthogonal to each other on a plane that is parallel to the major surface of a substrate. The z-axis is perpendicular to the major surface of the substrate, the positive z-axis direction indicates the upward direction, and the negative z-axis direction indicates the downward direction.

In the descriptions below, “connected” not only indicates that circuit elements are directly connected to each other with a connection terminal and/or a wire conductor but also indicates that the circuit elements are electrically connected to each other via another circuit element. “A is switchably connected to B” means that A can be connected to and disconnected from B, that is, A is connected to B via a switch. Here, “A is connected to B” encompasses “A is switchably connected to B”.

“C is connected between A and B” means that one end of C is connected to A and the other end of C is connected to “B” and means that C is connected in series in a path connecting A to B. “C is connected between the ground and a path connecting A to B” means that one end of C is connected to the path connecting A to B and the other end of C is connected to the ground and means that C is shunt-connected to the path connecting A to B. “Path connecting A to B” indicates a path formed by a conductor that electrically connects A and B to each other.

A “terminal” indicates a point at which a conductor in a circuit element ends. When the impedance of a conductor between circuit elements is sufficiently low, a terminal may be interpreted not only as a specific single point but also as any point on the conductor between the circuit elements or the entire conductor. A “node” refers to a point between circuit elements. When the impedance of a conductor between circuit elements is sufficiently low, a node can be interpreted not only as a specific single point but also as any point on the conductor between the circuit elements or the entire conductor.

Also, “a component is disposed on a substrate” may indicate that the component is disposed on the major surface of the substrate or the component is disposed in the substrate. “A component is disposed on the major surface of a substrate” indicates not only a case in which the component is disposed in contact with the major surface of the substrate but also a case in which the component is disposed above the major surface and not in contact with the major surface (e.g., the component is stacked on another component that is disposed in contact with the major surface). Also, “a component is disposed on the major surface of a substrate” may include a layout in which the component is disposed in a recess formed in the major surface. “A component is disposed in a substrate” not only indicates that the component is encapsulated in the substrate but also indicates a case in which the entirety of the component is disposed between two major surfaces of the substrate, but a part of the component is not covered by the substrate and a case in which only a part of the component is disposed inside the substrate. “Plan view of a substrate” indicates a view of an object that is orthographically projected onto an xy plane in the negative z-axis direction. “A overlaps B in plan view of a substrate” indicates that the region of A orthographically projected onto the xy plane overlaps the region of B orthographically projected onto the xy plane. “A is directly connected to B” means that A is physically in contact with and connected to B. Here, “A is directly connected to B” also includes a case in which A is connected to B via a joining material. “Joining material” refers to a substance that is provided between A and B for physical connection (joining) between A and B.

“Thickness of a wire on a wiring layer of a semiconductor substrate” refers to the length of the wire along the z-axis. The thicknesses of wires on different wiring layers are compared based on the average thicknesses of the wires. The average thickness of a wire is calculated by averaging the thicknesses of the center of the wire that are sampled at regular intervals in the direction of extension of the wire.

Terms such as “parallel” and “perpendicular” indicating relationships between elements, terms such as “linear” indicating shapes of elements, and numerical ranges do not only indicate their exact meanings but may also indicate substantially equivalent ranges that vary by, for example, about a few percent.

### First Embodiment

A first embodiment is described.

### 1.1. Circuit Configuration of Low-Noise Amplifier Circuit 1

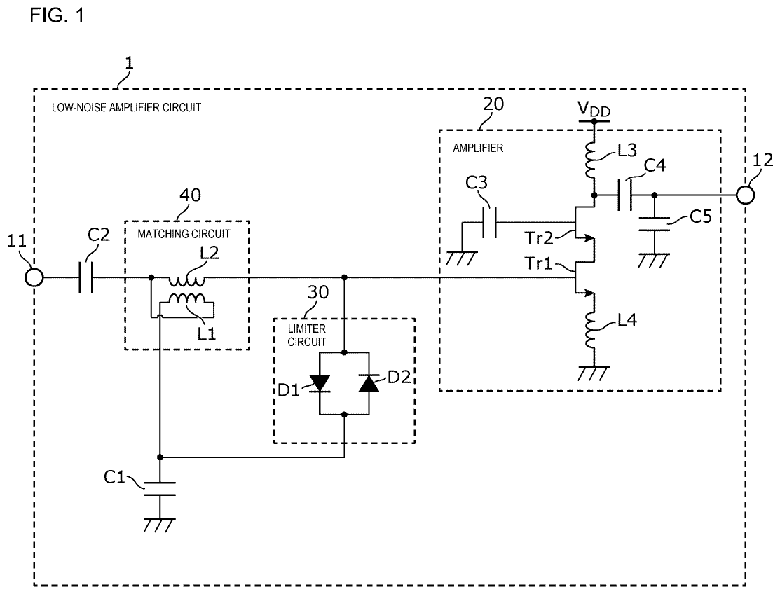

FIG. 1 is a circuit diagram of a low-noise amplifier circuit 1 according to the present embodiment. Here, FIG. 1 is an exemplary circuit diagram, and the low-noise amplifier circuit 1 may be implemented using any of various types of circuit implementation and circuit technologies. Therefore, the following descriptions of the low-noise amplifier circuit 1 should not be interpreted restrictively.

The low-noise amplifier circuit 1 includes an input terminal 11, an output terminal 12, an amplifier 20, a limiter circuit 30, a matching circuit 40, and capacitors C1 and C2.

The input terminal 11 is an external connection terminal of the low-noise amplifier circuit 1 and is a terminal for receiving radio frequency signals. The input terminal 11 is connected to an antenna outside the low-noise amplifier circuit 1 and is connected to the capacitor C2 inside the low-noise amplifier circuit 1.

The output terminal 12 is an external connection terminal of the low-noise amplifier circuit 1 and is a terminal for supplying radio frequency signals. The output terminal 12 is connected to, for example, a radio frequency integrated circuit (RFIC) outside the low-noise amplifier circuit 1 and is connected to the output end of the amplifier 20 inside the low-noise amplifier circuit 1.

The capacitor C1 is an example of a first capacitor and is connected between the limiter circuit 30 and the ground and between the matching circuit 40 and the ground. Specifically, one of two electrodes of the capacitor C1 is connected to the limiter circuit 30 and the matching circuit 40, and the other one of the two electrodes of the capacitor C1 is connected to the ground. The capacitor C1 can block direct-current components in a path connecting the limiter circuit 30 and the matching circuit 40 to the ground.

The capacitor C2 is an example of a second capacitor and is connected between the input terminal 11 and an inductor L2 of the matching circuit 40. Specifically, one of two electrodes of the capacitor C2 is connected to the input terminal 11, and the other one of the two electrodes of the capacitor C2 is connected to first ends of inductors L1 and L2. The capacitor C2 is a so-called coupling capacitor that can pass radio frequency components and block direct-current components in a path connecting the input terminal 11 to the amplifier 20.

### 1.1.1. Circuit Configuration of Amplifier 20

The amplifier 20 can amplify radio frequency signals using a power supply voltage V_{DD} supplied from a power supply. The amplifier 20 is connected between the input terminal 11 and the output terminal 12. Specifically, the input end of the amplifier 20 is connected to the input terminal 11 via the capacitor C2 and the matching circuit 40, and the output end of the amplifier 20 is connected to the output terminal 12.

The amplifier 20 includes cascode-connected transistors Tr1 and Tr2, inductors L3 and L4, and capacitors C3, C4, and C5.

The drain terminal of the transistor Tr1 is connected to the source terminal of the transistor Tr2, and the source terminal of the transistor Tr1 is connected to the ground via the inductor L4. The gate terminal of the transistor Tr1 is connected to the input terminal 11 via the capacitor C2 and the matching circuit 40.

The drain terminal of the transistor Tr2 is connected to the power supply via the inductor L3 and is connected to the output terminal 12 via the capacitor C4. The source terminal of the transistor Tr2 is connected to the drain terminal of the transistor Tr1. The gate terminal of the transistor Tr2 is connected to the ground via the capacitor C3.

As the transistors Tr1 and Tr2, field-effect transistors (FET), such as metal oxide semiconductor field-effect transistors (MOSFET), are used. However, the transistors Tr1 and Tr2 are not limited to FETs. The transistors Tr1 and Tr2 may be bipolar transistors.

The inductor L3 is a so-called choke inductor and is connected between the power supply and the transistor Tr2. Specifically, a first end of the inductor L3 is connected to the drain terminal of the transistor Tr2, and a second end of the inductor L3 is connected to the power supply.

The inductor L4 is a so-called source inductor and is connected between the transistor Tr1 and the ground. Specifically, a first end of the inductor L4 is connected to the source terminal of the transistor Tr1, and a second end of the inductor L4 is connected to the ground.

The capacitor C3 is connected between the transistor Tr2 and the ground. Specifically, one of two electrodes of the capacitor C3 is connected to the gate terminal of the transistor Tr2, and the other one of the two electrodes of the capacitor C3 is connected to the ground.

The capacitor C4 is connected between the output terminal 12 and a path connecting the transistor Tr2 to the inductor L3. Specifically, one of two electrodes of the capacitor C4 is connected to a path connecting the drain terminal of the transistor Tr2 to the first end of the inductor L3, and the other one of the two electrodes of the capacitor C4 is connected to the output terminal 12.

The capacitor C5 is connected between the ground and a path connecting the capacitor C4 to the output terminal 12. Specifically, one of two electrodes of the capacitor C5 is connected to the path connecting the capacitor C4 to the output terminal 12, and the other one of the two electrodes of the capacitor C5 is connected to the ground.

The amplifier 20 is not limited to a common-source amplifier. For example, the amplifier 20 may be a common-gate amplifier. Also, the amplifier 20 does not have to include the cascode-connected transistors Tr1 and Tr2. For example, the amplifier 20 may be configured to include the transistor Tr1 and not to include the transistor Tr2. Also, in the circuit configuration of the amplifier 20, additional circuit elements and/or wires may be inserted in paths connecting the circuit elements and the signal paths illustrated in FIG. 1. For example, a path connecting the drain terminal and the gate terminal of the transistor Tr2 via a capacitor may be provided.

### 1.1.2. Circuit Configuration of Limiter Circuit 30

The limiter circuit 30 is connected between the ground and a path connecting the matching circuit 40 to the amplifier 20. Specifically, a first end of the limiter circuit 30 is connected to the path connecting the matching circuit 40 to the input end of the amplifier 20, and a second end of the limiter circuit 30 is connected to the ground via the capacitor C1.

The limiter circuit 30 includes two diodes D1 and D2 that are connected in parallel in opposite directions. The limiter circuit 30 can limit the signal voltage to a voltage amplitude determined by the forward voltage (for example, from 0.4 V to 0.7 V) of the diodes D1 and D2. Specifically, a diode with a forward voltage applied enters a conductive state and can limit a voltage exceeding the forward voltage. In other words, the limiting voltage of the limiter circuit 30 equals the forward voltage of the diodes D1 and D2. Here, additional diodes may be connected in series with each of the diodes D1 and D2, and the limiting voltage of the limiter circuit 30 may be adjusted based on the number of diodes connected in series. Also, the limiter circuit 30 may be implemented by a diode-connected MOSFET or a diode-connected bipolar transistor.

### 1.1.3 Circuit Configuration of Matching Circuit 40

The matching circuit 40 is a transmission line transformer (TLT) that can shift the phase and convert the impedance. However, the matching circuit 40 is not limited to a TLT. The matching circuit 40 includes the inductors L1 and L2.

The inductor L1 is an example of a first inductor and is a so-called auxiliary line. The inductor L1 is connected between the ground and the path connecting the input terminal 11 to the input end of the amplifier 20. Specifically, a first end of the inductor L1 is connected to a path connecting the capacitor C2 to the inductor L2, and a second end of the inductor L1 is connected to the ground via the capacitor C1.

The inductor L2 is an example of a second inductor and is a so-called main line. The inductor L2 is connected between the input terminal 11 and the input end of the amplifier 20. Specifically, a first end of the inductor L2 is connected to the input terminal 11 via the capacitor C2, and a second end of the inductor L2 is connected to the input end of the amplifier 20.

The inductors L1 and L2 are configured to be able to be coupled to each other. Also, the first ends of the inductors L1 and L2 are connected to each other, and a first direction from the first end to the second end of the inductor L1 is opposite a second direction from the first end to the second end of the inductor L2.

### 1.2. Implementation Example of Low-Noise Amplifier Circuit 1

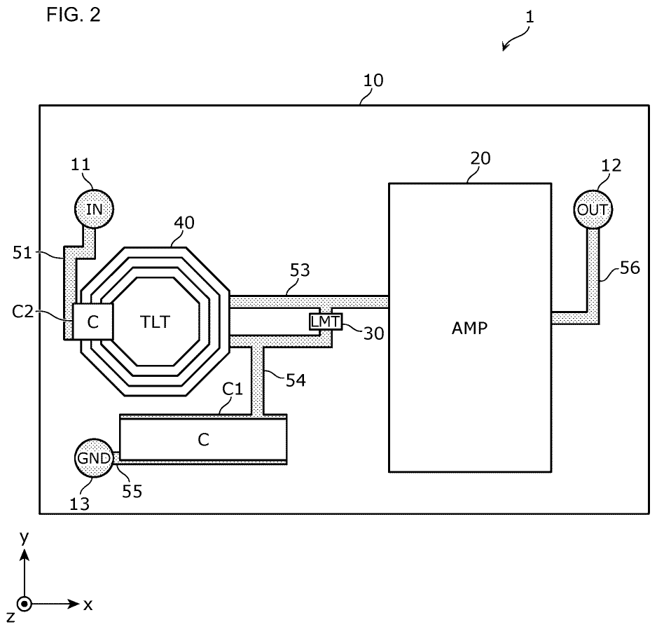

Next, an implementation example of the low-noise amplifier circuit 1 with the above-described circuit configuration is described with reference to FIG. 2. FIG. 2 is a layout diagram of the low-noise amplifier circuit 1 according to the present embodiment.

In FIG. 2, labels are provided for components to facilitate the understanding of the layout of the components. However, the labels do not have to be provided for actual components.

Here, FIG. 2 illustrates an exemplary layout of the low-noise amplifier circuit 1, and the low-noise amplifier circuit 1 may be implemented by using any of various types of circuit implementation and circuit technologies. Therefore, the following descriptions of the low-noise amplifier circuit 1 should not be interpreted restrictively.

The low-noise amplifier circuit 1 is implemented as a semiconductor integrated circuit including multiple wiring layers disposed on a semiconductor substrate 10. The multiple wiring layers include at least a first layer, a second layer, or a third layer in this order from the side closer to the semiconductor substrate 10. Metal films that can be formed on or in the second layer and the third layer are thicker than a metal film that can be formed on or in the first layer. For example, the thickness of a metal film on each of the second layer and the third layer is several micrometers, and the thickness of a metal film on the first layer is about one tenth of the metal film on each of the second layer and the third layer.

The semiconductor substrate 10 is formed of a semiconductor material and is sometimes referred to as a die or a chip. Examples of semiconductor materials of the semiconductor substrate 10 include, but are not limited to, silicon single crystal, gallium nitride (GaN), and silicon carbide (SiC).

The input terminal 11 (IN) is connected to a first electrode of the capacitor C2 (C) via a wire 51 formed on or in the second layer and/or the third layer. A second electrode of the capacitor C2 is directly connected to the first ends of the inductors L1 and L2 of the matching circuit 40 (TLT). The second end of the inductor L2 of the matching circuit 40 is connected to the first end of the limiter circuit 30 (LMT) and the input end of the amplifier 20 (AMP) via a wire 53 formed on or in the second layer and/or the third layer. The second end of the inductor L1 of the matching circuit 40 is connected to the second end of the limiter circuit 30 (LMT) and a first electrode of the capacitor C1 (C) via a wire 54 formed on or in the second layer and/or the third layer. A second electrode of the capacitor C1 is connected to a ground terminal 13 (GND) via a wire 55 formed on or in the second layer and/or the third layer. The output end of the amplifier 20 is connected to the output terminal 12 (OUT) via a wire 56 formed on or in the second layer and/or the third layer.

### 1.3. Implementation Examples of Capacitor C2 and Matching Circuit 40

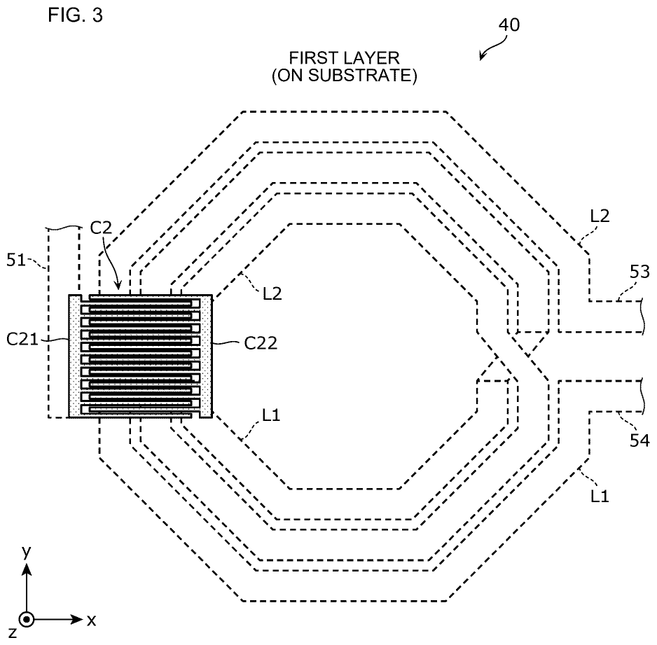

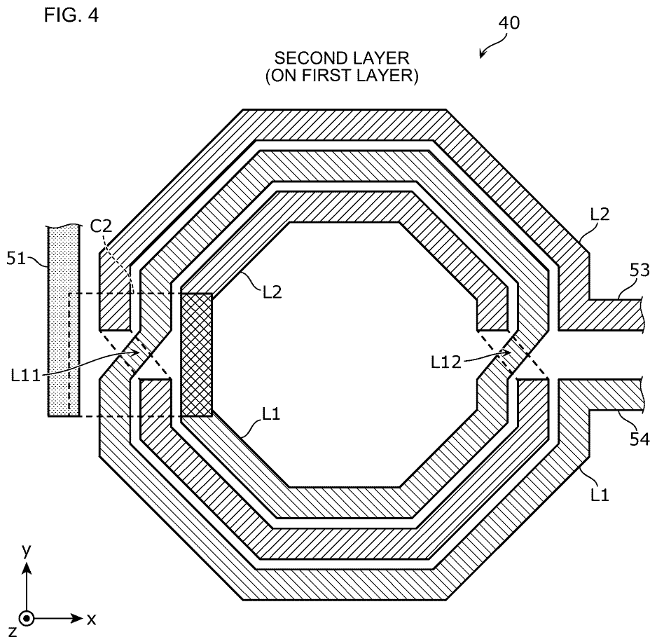

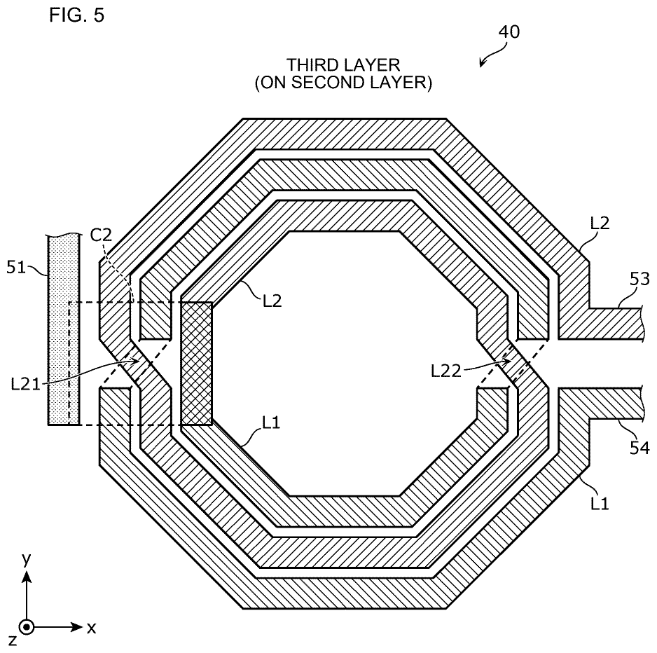

Details of configurations of the capacitor C2 and the matching circuit 40 are described below with reference to FIGS. 3, 4, and 5. FIGS. 3 to 5 are plan views of the first layer, the second layer, and the third layer of the capacitor C2 and the matching circuit 40 according to the present embodiment. In FIGS. 3 to 5, elements and wires on other layers are represented by dotted lines.

Here, FIGS. 3 to 5 illustrate exemplary configurations of the capacitor C2 and the matching circuit 40, and the capacitor C2 and the matching circuit 40 may be implemented by using any of various types of circuit implementation and circuit technologies. Therefore, the following descriptions of the capacitor C2 and the matching circuit 40 should not be interpreted restrictively.

The capacitor C2 is a metal-oxide-metal (MOM) capacitor and is disposed to intersect the matching circuit 40. The capacitor C2 includes two comb-shaped electrodes C21 and C22 formed by wires on the first layer. The two comb-shaped electrodes C21 and C22 are arranged to face and engage each other, and an oxide film (e.g., SiO₂) is provided between the two comb-shaped electrodes C21 and C22. The comb-shaped electrode C21 is an example of a first electrode and is connected to the input terminal 11 via the wire 51. The comb-shaped electrode C22 is an example of a second electrode and is directly connected to the first ends of the inductors L1 and L2 on the inner side of spiral patterns. The capacitor C2 is not limited to a MOM capacitor. For example, the capacitor C2 may be a metal-insulator-metal (MIM) capacitor.

The inductors L1 and L2 of the matching circuit 40 are formed by wires on the second layer and the third layer. Specifically, the inductor L1 is formed by a wire that extends counterclockwise from the inner side toward the outer side to form a spiral pattern. The inductor L2 is formed by a wire that extends clockwise from the inner side toward the outer side to form a spiral pattern. The first ends of the inductors L1 and L2 on the inner side of the spiral patterns are directly connected to the comb-shaped electrode C22 of the capacitor C2. The second ends of the inductors L1 and L2 on the outer side of the spiral patterns are connected to the wires 54 and 53, respectively.

In plan view of the semiconductor substrate 10, a portion L11 of the inductor L1 overlaps a portion L21 of the inductor L2, and a portion L12 of the inductor L1 overlaps a portion L22 of the inductor L2. Also, in plan view of the semiconductor substrate 10, the capacitor C2 at least partially overlaps the portion L11 of the inductor L1 or the portion L21 of the inductor L2.

### 1.4. Summary

As described above, the low-noise amplifier circuit 1 according to the present embodiment includes the input terminal 11, the output terminal 12, the amplifier 20 connected between the input terminal 11 and the output terminal 12, the limiter circuit 30 including two diodes D1 and D2 that are connected in parallel in opposite directions between the ground and the path connecting the input terminal 11 to the input end of the amplifier 20, the matching circuit 40 including the inductor L1 that is connected between the ground and the path connecting the input terminal 11 to the input end of the amplifier 20, and the capacitor C1 that is connected between the limiter circuit 30 and the ground and between the matching circuit 40 and the ground.

With this configuration, a capacitor connected between the limiter circuit 30 and the ground and a capacitor connected between the matching circuit 40 and the ground can be implemented by the same capacitor. Thus, the circuit area for the capacitor may be reduced, the layout flexibility may be increased, and the wiring length may be reduced. This, in turn, reduces the parasitic capacitance due to the wiring and thereby improves the NF of the low-noise amplifier circuit 1.

Also, for example, in the low-noise amplifier circuit 1 of the present embodiment, the matching circuit 40 may be a transmission line transformer and may further include the inductor L2 that is connected between the input terminal 11 and the input end of the amplifier 20.

With this configuration, even when the matching circuit 40 is a transmission line transformer, the NF of the low-noise amplifier circuit 1 may be improved.

Also, for example, the low-noise amplifier circuit 1 according to the present embodiment may further include the semiconductor substrate 10 and the capacitor C2 connected between the input terminal 11 and the inductor L2; and the inductor L1, the inductor L2, and the capacitor C2 may be formed by wires on the semiconductor substrate 10. In plan view of the semiconductor substrate 10, a portion of the inductor L1 may overlap a portion of the inductor L2; and in plan view of the semiconductor substrate 10, the capacitor C2 may at least partially overlap the portion of the inductor L1 or the portion of the inductor L2.

With this configuration, the capacitor C2 can be stacked on the overlapping portions of the inductors L1 and L2. If a normal wire is stacked on the overlapping portions of the inductors L1 and L2, the thickness of the wire needs to be reduced, and the wiring resistance may increase. In contrast, the characteristic degradation of the capacitor C2 is small even when the wire thickness is reduced. Accordingly, stacking the capacitor C2 on the overlapping portions of the inductors L1 and L2 may reduce the increase in the wiring resistance and thereby improve the NF of the low-noise amplifier circuit 1.

Also, for example, in the low-noise amplifier circuit 1 according to the present embodiment, the inductors L1 and L2 may be formed by wires extending from the inner side toward the outer side in spiral patterns that wind in opposite directions in plan view of the semiconductor substrate 10; the input terminal 11 may be disposed outside the spiral patterns; and the capacitor C2 may include a first electrode (e.g., comb-shaped electrode C21) connected to the input terminal 11 and a second electrode (e.g., comb-shaped electrode C22) connected to the first ends of the inductors L1 and L2 on the inner side of the spiral patterns.

This configuration makes it possible to use the capacitor C2 in place of a wire that intersects the inductors L1 and L2, which are formed by wires extending in spiral patterns that wind in opposite directions, from the outer side toward the inner side of the spiral patterns. This, in turn, may reduce the increase in wiring resistance and improve the NF of the low-noise amplifier circuit 1.

Also, for example, in the low-noise amplifier circuit 1 according to the present embodiment, the second electrode (e.g., comb-shaped electrode C22) of the capacitor C2 may be directly connected to the first ends of the inductors L1 and L2.

This eliminates the need to provide wires for connecting the inductors L1 and L2 to the capacitor C2, allowing the wiring resistance to be reduced and the NF of the low-noise amplifier circuit 1 to be improved.

Also, for example, in the low-noise amplifier circuit 1 according to the present embodiment, multiple wiring layers, which include at least the first layer, the second layer, or the third layer in this order from the side closer to the semiconductor substrate 10, may be formed on the semiconductor substrate 10; the inductors L1 and L2 may be formed by wires on the second layer and the third layer; the capacitor C2 may be formed by wires on the first layer; and the thickness of the wires on the first layer may be less than the thickness of the wires on the second layer and the third layer.

This makes it possible to form the capacitor C2, the characteristics of which are less degraded by the thinness of wires, by using thinner wires on the first layer. This, in turn, may suppress the characteristic degradation of the low-noise amplifier circuit 1.

Also, for example, in the low-noise amplifier circuit 1 according to the present embodiment, the capacitor C2 may be a MOM capacitor.

This may simplify the manufacturing process and reduce the circuit area.

### Second Embodiment

Next, a second embodiment is described. The present embodiment differs primarily from the first embodiment in that the capacitor C1, instead of the capacitor C2, overlaps the transmission line transformer in the implementation of the low-noise amplifier circuit 1. Below, features of the present embodiment that are different from the first embodiment are mainly described with reference to the drawings.

The circuit configuration of a low-noise amplifier circuit 1A according to the present embodiment is the same as that of the low-noise amplifier circuit 1 according to the first embodiment. Therefore, illustration and descriptions of the circuit configuration are omitted. In the present embodiment, the low-noise amplifier circuit 1A does not have to include the capacitor C2.

### 2.1. Implementation Example of Low-Noise Amplifier Circuit 1A

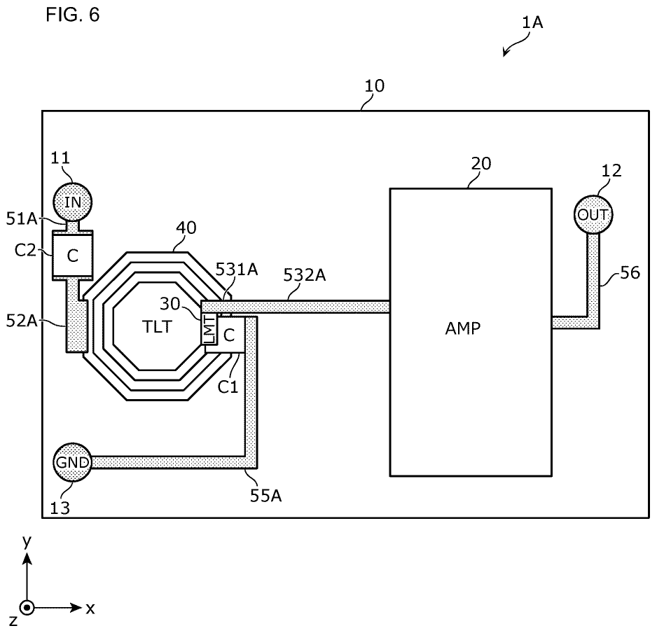

An implementation example of the low-noise amplifier circuit 1A is described with reference to FIG. 6. FIG. 6 is a layout diagram of the low-noise amplifier circuit 1A according to the present embodiment.

In FIG. 6, labels are provided for components to facilitate the understanding of the layout of the components. However, the labels do not have to be provided for actual components.

Here, FIG. 6 illustrates an exemplary layout of the low-noise amplifier circuit 1A, and the low-noise amplifier circuit 1A may be implemented by using any of various types of circuit implementation and circuit technologies. Therefore, the following descriptions of the low-noise amplifier circuit 1A should not be interpreted restrictively.

Similarly to the low-noise amplifier circuit 1 according to the first embodiment, the low-noise amplifier circuit 1A is implemented as a semiconductor integrated circuit including multiple wiring layers on the semiconductor substrate 10.

The input terminal 11 (IN) is connected to the first electrode of the capacitor C2 (C) via a wire 51A formed on or in the second layer and/or the third layer. The second electrode of the capacitor C2 is connected to the first ends of the inductors L1 and L2 of the matching circuit 40 (TLT) via a wire 52A formed on or in the second layer and/or the third layer. The second end of the inductor L2 of the matching circuit 40 is connected directly to the first end of the limiter circuit 30 (LMT). The second end of the inductor L2 is also connected to the input end of the amplifier 20 (AMP) via a wire 531A and a wire 532A. The wire 531A is formed on or in the first layer. The wire 532A is formed on or in the second layer and/or the third layer. The second end of the inductor L1 of the matching circuit 40 is directly connected to the second end of the limiter circuit 30. The second end of the inductor L1 is also directly connected to the first electrode of the capacitor C1 (C). The second electrode of the capacitor C1 is connected to the ground terminal 13 (GND) via a wire 55A formed on or in the second layer and/or the third layer. The output end of the amplifier 20 is connected to the output terminal 12 (OUT) via a wire 56 formed on or in the second layer and/or the third layer.

### 2.2. Implementation Examples of Capacitor C1 and Matching Circuit 40

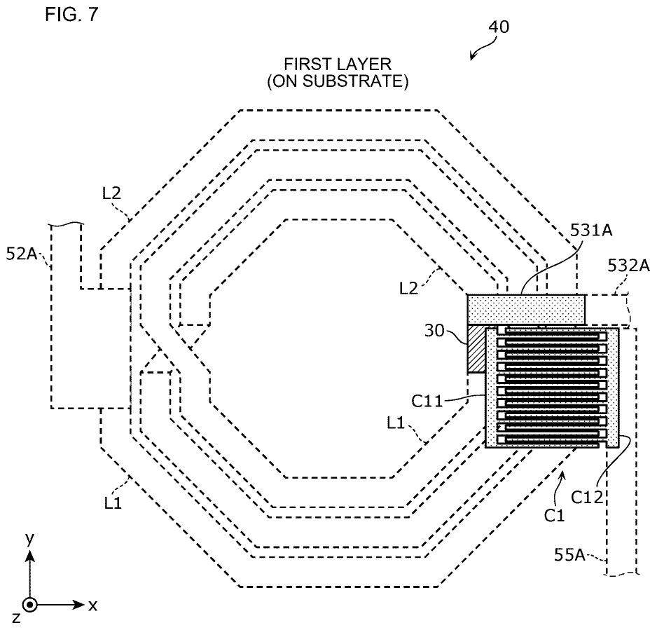

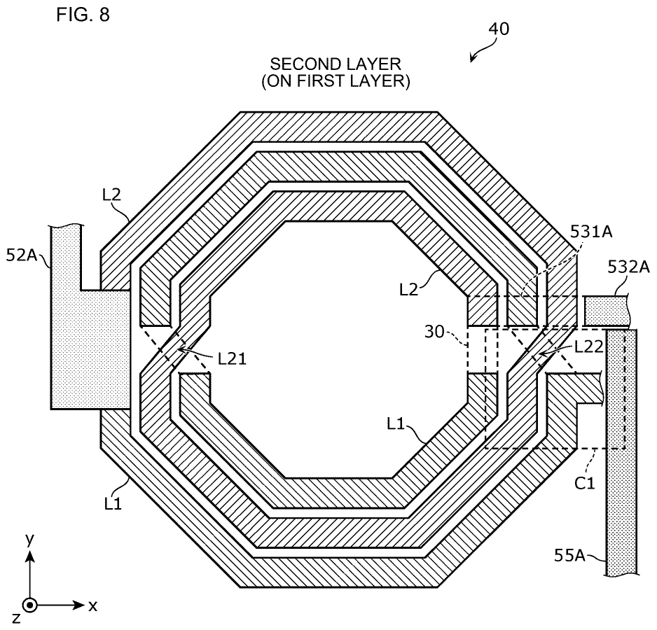

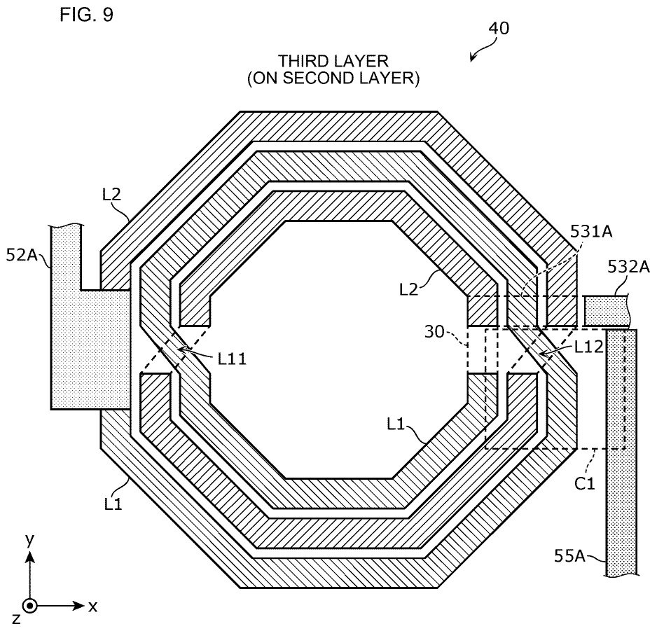

Details of configurations of the capacitor C1 and the matching circuit 40 are described below with reference to FIGS. 7, 8, and 9. FIGS. 7 to 9 are plan views of the first layer, the second layer, and the third layer of the capacitor C1 and the matching circuit 40 according to the present embodiment. In FIGS. 7 to 9, elements and wires on other layers are represented by dotted lines.

Here, FIGS. 7 to 9 illustrate exemplary configurations of the capacitor C1 and the matching circuit 40, and the capacitor C1 and the matching circuit 40 may be implemented by using any of various types of circuit implementation and circuit technologies. Therefore, the following descriptions of the capacitor C1 and the matching circuit 40 should not be interpreted restrictively.

The capacitor C1 is a MOM capacitor and is disposed to intersect the matching circuit 40. The capacitor C1 includes two comb-shaped electrodes C11 and C12 formed by wires on the first layer. The two comb-shaped electrodes C11 and C12 are arranged to face and engage each other, and an oxide film (e.g., SiO₂) is provided between the two comb-shaped electrodes C11 and C12. The comb-shaped electrode C11 is an example of a first electrode, is directly connected to the second end of the inductor L1 on the inner side of the spiral patterns, and is also directly connected to the second end of the limiter circuit 30. The comb-shaped electrode C12 is an example of a second electrode and is connected to a wire 55A.

The inductors L1 and L2 of the matching circuit 40 are formed by wires on the second layer and the third layer. Specifically, the inductor L1 is formed by a wire that extends counterclockwise in a spiral pattern from the outer side toward the inner side. The inductor L2 is formed by a wire that extends clockwise in a spiral pattern from the outer side toward the inner side. The first ends of the inductors L1 and L2 on the outer side of the spiral patterns are connected to a wire 52A. The second end of the inductor L1 on the inner side of the spiral patterns is directly connected to the limiter circuit 30 and is also directly connected to the comb-shaped electrode C11 of the capacitor C1. The second end of the inductor L2 on the inner side of the spiral patterns is directly connected to the limiter circuit 30 and is also connected to a wire 531A.

In plan view of the semiconductor substrate 10, the portion L11 of the inductor L1 overlaps the portion L21 of the inductor L2, and the portion L12 of the inductor L1 overlaps the portion L22 of the inductor L2. Also, in plan view of the semiconductor substrate 10, the capacitor C1 at least partially overlaps the portion L12 of the inductor L1 or the portion L22 of the inductor L2.

### 2.3. Summary

As described above, the low-noise amplifier circuit 1A according to the present embodiment may further include the semiconductor substrate 10; the inductors L1 and L2 and the capacitor C1 may be formed by wires on the semiconductor substrate 10; a portion of the inductor L1 may overlap a portion of the inductor L2 in plan view of the semiconductor substrate 10; and the capacitor C1 may at least partially overlap the portion of the inductor L1 or the portion of the inductor L2 in plan view of the semiconductor substrate 10.

With this configuration, the capacitor C1 can be stacked on the overlapping portions of the inductors L1 and L2. If a normal wire is stacked on the overlapping portions of the inductors L1 and L2, the thickness of the wire needs to be reduced, and the wiring resistance may increase. In contrast, the characteristic degradation of the capacitor C1 is small even when the wire thickness is reduced. Accordingly, stacking the capacitor C1 on the overlapping portions of the inductors L1 and L2 may reduce the increase in the wiring resistance and thereby improve the NF of the low-noise amplifier circuit 1A.

Also, for example, in the low-noise amplifier circuit 1A according to the present embodiment, the inductors L1 and L2 may be formed by wires extending from the outer side toward the inner side in spiral patterns that wind in opposite directions in plan view of the semiconductor substrate 10, the input terminal 11 may be disposed outside the spiral patterns and connected to the first ends of the inductors L1 and L2 on the outer side of the spiral patterns, the low-noise amplifier circuit 1A may further include the ground terminal 13 disposed outside the spiral patterns, and the capacitor C1 may include a first electrode (e.g., comb-shaped electrode C11) connected to the second end of the inductor L1 on the inner side of the spiral patterns and a second electrode (e.g., comb-shaped electrode C12) connected to the ground terminal 13.

This configuration makes it possible to use the capacitor C1 in place of a wire that intersects the inductors L1 and L2, which are formed by wires extending in spiral patterns that wind in opposite directions, from the inner side toward the outer side of the spiral patterns. This, in turn, may reduce the increase in wiring resistance and improve the NF of the low-noise amplifier circuit 1A.

For example, in the low-noise amplifier circuit 1A according to the present embodiment, the first electrode (e.g., comb-shaped electrode C11) of the capacitor C1 may be directly connected to the second end of the inductor L1.

This eliminates the need to provide a wire for connecting the inductor L1 to the capacitor C1 and thereby may reduce the wiring resistance and improve the NF of the low-noise amplifier circuit 1A.

For example, in the low-noise amplifier circuit 1A according to the present embodiment, multiple wiring layers, which include at least the first layer, the second layer, or the third layer in this order from the side closer to the semiconductor substrate 10, may be formed on the semiconductor substrate 10; the inductors L1 and L2 may be formed by wires on the second layer and the third layer; the capacitor C1 may be formed by wires on the first layer; and the thickness of the wires on the first layer may be less than the thickness of the wires on the second layer and the third layer.

This configuration makes it possible to form the capacitor C1, the characteristics of which are less degraded by the thinness of wires, with thinner wires on the first layer. This, in turn, may suppress the characteristic degradation of the low-noise amplifier circuit 1A.

For example, in the low-noise amplifier circuit 1A according to the present embodiment, the capacitor C1 may be a MOM capacitor.

This may simplify the manufacturing process and reduce the circuit area. In the configuration described in the second embodiment, the wires forming the first inductor L1 and second inductor L2 on the second and third layers are spiral-shaped and define a physical footprint that substantially encompasses the footprint of the first capacitor C1. This specific spatial arrangement provides a technical solution to the physical problem of parasitic capacitance and signal loss in semiconductor substrates. By stacking the larger spiral inductors directly over the smaller capacitor C1, the circuit achieves a high-density layout that minimizes total wiring length between the matching circuit 40, the limiter circuit 30, and the capacitor C1. Furthermore, because the capacitor C1 is disposed on the first layer (closer to the substrate 10) and is substantially encompassed by the inductors above it, the layout effectively uses the capacitor structure in place of a traditional intersecting wire. This reduces the overall wiring resistance that would otherwise degrade the Noise Figure (NF), thereby improving the technical operation of the low-noise amplifier circuit itself through optimized electromagnetic coupling and reduced substrate-induced losses.

### Other Embodiments

Low-noise amplifier circuits according to the embodiments of the present disclosure are described above. However, the present disclosure is not limited to the above-described embodiments. Other embodiments implemented by combining components in the above embodiments, variations obtained by applying various modifications conceivable by a person skilled in the art to the above embodiments without departing from the spirit of the present disclosure, and various devices including the low-noise amplifier circuits described above are also included in the present disclosure.

For example, in the circuit configurations of the low-noise amplifier circuits according to the above embodiments, additional circuit elements and wires may be inserted in paths connecting the circuit elements and the signal paths illustrated in the drawings. For example, each of the low-noise amplifier circuits 1 and 1A may include a bias circuit that applies a bias voltage to the transistor Tr1.

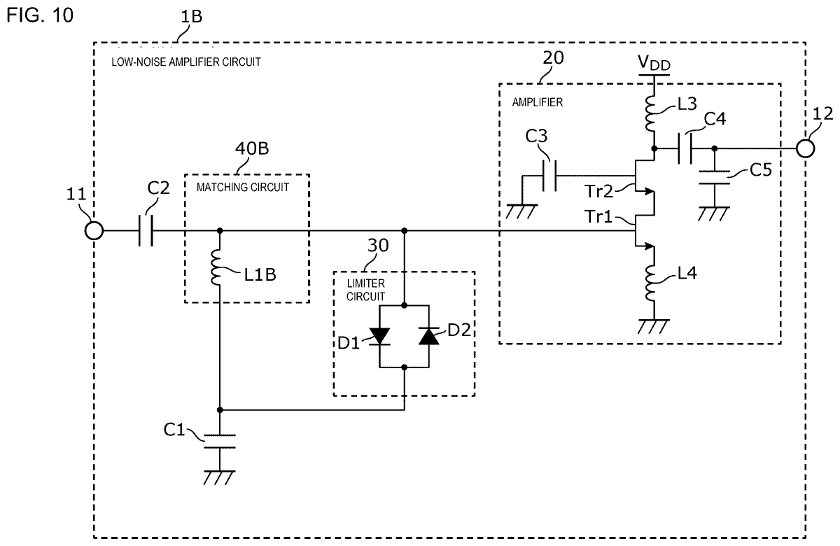

Also, for example, the matching circuit 40 included in each of the low-noise amplifier circuits 1 and 1A of the above embodiments does not have to be a transmission line transformer. For example, the matching circuit 40 may have a circuit configuration illustrated in FIG. 10.

FIG. 10 is a circuit diagram of a low-noise amplifier circuit 1B according to another embodiment. As illustrated in FIG. 10, the low-noise amplifier circuit 1B differs from the low-noise amplifier circuits 1 and 1A according to the first and second embodiments in that the low-noise amplifier circuit 1B includes a matching circuit 40B instead of the matching circuit 40. The matching circuit 40B includes an inductor L1B. The inductor L1B is an example of a first inductor and is connected between the ground and a path connecting the input terminal 11 to the input end of the amplifier 20. Specifically, a first end of the inductor L1B is connected to a path connecting the capacitor C2 to the input end of the amplifier 20, and a second end of the inductor L1B is connected to the ground via the capacitor C1. Even with the low-noise amplifier circuit 1B including the matching circuit 40B described above, similarly to the low-noise amplifier circuits 1 and 1A, a capacitor connected between the limiter circuit 30 and the ground and a capacitor connected between the matching circuit 40B and the ground can be implemented by the same capacitor. This may reduce the circuit area for the capacitor, increase the layout flexibility, and reduce the wiring length. This, in turn, may reduce the parasitic capacitance due to the wiring and thereby improve the NF of the low-noise amplifier circuit 1B.

In the above embodiments, the multiple wiring layers on the semiconductor substrate 10 include the first layer on which thinner metal wiring is formed and the second and third layers on which thicker metal wiring is formed. However, the multiple wiring layers are not limited to this example. For example, the multiple wiring layers do not have to include the second layer or the third layer. Also, for example, the multiple wiring layers may further include a fourth Layer on which metal wiring, which has a thickness similar to the thickness of the metal wiring on the second and third layers, is formed.

In each of the above embodiments, the low-noise amplifier circuit is included in a semiconductor integrated circuit. However, the present disclosure is not limited to this example. As another example, a part or the entirety of the low-noise amplifier circuit does not have to be included in the semiconductor integrated circuit. For example, the low-noise amplifier circuit may be implemented as a discrete component.

The physical integration of the first capacitor C1 (or second capacitor C2) as a metal-oxide-metal (MOM) capacitor specifically configured to overlap the spiral patterns of the first inductor L1 and second inductor L2 in plan view provides a specific technical solution to the problem of parasitic capacitance and signal loss inherent in semiconductor substrates. By utilizing the first layer (which is closer to the semiconductor substrate 10) for the capacitor and the thicker second and third layers for the inductors, the circuit achieves a high-density footprint that minimizes total wiring length. This specific spatial arrangement reduces the physical area vulnerable to substrate-induced losses and decreases parasitic capacitance that would otherwise degrade the Noise Figure (NF) if a standard wire were used to intersect the inductors. Consequently, an improvement to the operation of the low-noise amplifier circuit itself may be realized by optimizing electromagnetic coupling and reducing ohmic resistance through the elimination of redundant interconnects.

The present disclosure can be widely used for communication devices, such as mobile phones, as a low-noise amplifier circuit disposed in a front-end unit.

What is claimed is:

1. A low-noise amplifier circuit comprising:
an input terminal;
an output terminal;
an amplifier connected between the input terminal and the output terminal;
a limiter circuit including a first diode and a second diode connected in parallel in opposite directions between a ground and a path connecting the input terminal to an input end of the amplifier;
a matching circuit including a first inductor connected between the ground and the path connecting the input terminal to the input end of the amplifier; and
a first capacitor connected between the limiter circuit and the ground and between the matching circuit and the ground.

2. The low-noise amplifier circuit according to Claim 1, wherein
the matching circuit includes a transmission line transformer and further includes a second inductor connected between the input terminal and the input end of the amplifier.

3. The low-noise amplifier circuit according to Claim 2, further comprising:
a semiconductor substrate; and
a second capacitor connected between the input terminal and the second inductor, wherein
the first inductor, the second inductor, and the second capacitor are formed by wires on the semiconductor substrate;
in plan view of the semiconductor substrate, a portion of the first inductor overlaps a portion of the second inductor; and
in plan view of the semiconductor substrate, the second capacitor at least partially overlaps the portion of the first inductor or the portion of the second inductor.

4. The low-noise amplifier circuit according to Claim 3, wherein
the first inductor and the second inductor are formed by wires that extend from an inner side toward an outer side in spiral patterns that wind in opposite directions in plan view of the semiconductor substrate;
the input terminal is disposed outside the spiral patterns; and
the second capacitor includes a first electrode connected to the input terminal and a second electrode connected to first ends of the first inductor and the second inductor on the inner side of the spiral patterns.

5. The low-noise amplifier circuit according to Claim 4, wherein
the second electrode is directly connected to the first ends of the first inductor and the second inductor.

6. The low-noise amplifier circuit according to Claim 3, wherein
multiple wiring layers are formed on the semiconductor substrate and include at least a first layer, a second layer, or a third layer in this order from a side closer to the semiconductor substrate;
the first inductor and the second inductor are formed by wires on the second layer and the third layer;
the second capacitor is formed by wires on the first layer; and
a thickness of the wires on the first layer is less than a thickness of the wires on the second layer and the third layer.

7. The low-noise amplifier circuit according to Claim 3, wherein
the second capacitor is a metal-oxide-metal (MOM) capacitor.

8. The low-noise amplifier circuit according to Claim 2, further comprising:
a semiconductor substrate, wherein
the first inductor, the second inductor, and the first capacitor are formed by wires on the semiconductor substrate;
in plan view of the semiconductor substrate, a portion of the first inductor overlaps a portion of the second inductor; and
in plan view of the semiconductor substrate, the first capacitor at least partially overlaps the portion of the first inductor or the portion of the second inductor.

9. The low-noise amplifier circuit according to Claim 8, wherein
the first inductor and the second inductor are formed by wires that extend from an outer side toward an inner side in spiral patterns that wind in opposite directions in plan view of the semiconductor substrate;
the input terminal is disposed outside the spiral patterns and is connected to first ends of the first inductor and the second inductor on the outer side of the spiral patterns;
the low-noise amplifier circuit further comprises a ground terminal disposed outside the spiral patterns; and
the first capacitor includes a first electrode connected to a second end of the first inductor on the inner side of the spiral patterns and a second electrode connected to the ground terminal.

10. The low-noise amplifier circuit according to Claim 9, wherein
the first electrode is directly connected to the second end of the first inductor.

11. The low-noise amplifier circuit according to Claim 8, wherein
multiple wiring layers are formed on the semiconductor substrate and include at least a first layer, a second layer, or a third layer in this order from a side closer to the semiconductor substrate;
the first inductor and the second inductor include wires on the second layer and the third layer;
the first capacitor includes wires on the first layer; and
a thickness of the wires on the first layer is less than a thickness of the wires on the second layer and the third layer.

12. The low-noise amplifier circuit according to Claim 11, wherein the wires on the second layer and the third layer are spiral-shaped and have a footprint that substantially encompasses a footprint of the first capacitor.

13. The low-noise amplifier circuit according to Claim 8, wherein
the first capacitor is a MOM capacitor.

14. The low-noise amplifier circuit according to Claim 3, wherein the second capacitor is located directly beneath the first inductor and the second inductor.

15. The low-noise amplifier circuit according to Claim 1, further comprising a bias circuit configured to provide a bias voltage to the amplifier.

16. The low-noise amplifier circuit according to Claim 1, wherein
the first capacitor is connected in series with the first diode and the second diode between the path and the ground; and
the first capacitor is connected in series with the first inductor between the path and the ground.

17. The low-noise amplifier circuit according to Claim 16, wherein
the matching circuit includes a second inductor connected in series with the first capacitor between the path and the ground.

18. The low-noise amplifier circuit of claim 1, wherein the first inductor and the first capacitor are integrated on a semiconductor substrate including a plurality of wiring layers, and the first capacitor is disposed in a layer closer to the semiconductor substrate than the first inductor.

19. A radio-frequency (RF) front-end module comprising:
an antenna switch; and
the low-noise amplifier circuit according to claim 1 electrically connected to the antenna switch.

20. A method of manufacturing a low-noise amplifier circuit, the method comprising:
forming a first capacitor on a first metal layer of a substrate;
forming a transmission line transformer including a first inductor and a second inductor on a second metal layer and a third metal layer, respectively, such that, in plan view, the transmission line transformer overlaps the first capacitor; and
electrically connecting the first capacitor to both a limiter circuit and a matching circuit.
